(19) United States
(12) Patent Application Publication
(10) Pub. No.: US 2007/0296027 A1
(43) Pub. Date: Dec. 27, 2007

(54) CMOS DEVICES COMPRISING A CONTINUOUS STRESSOR LAYER WITH REGIONS OF OPPOSITE STRESSES, AND METHODS OF FABRICATING THE SAME

(75) Inventors: Haining Yang, Wappingers Falls, NY (US); Wai-Kin Li, Beacon, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/425,516

(22) Filed: Jun. 21, 2006

(51) Int. Cl. H01L 21/8234

(52) U.S. Cl. 257/327; 438/197

(57) ABSTRACT

The present invention relates to complementary metal-oxide-semiconductor (CMOS) devices having a continuous dielectric stressor layer containing regions of opposite stresses. Specifically, each CMOS device of the present invention includes at least one n-channel field effect transistor (n-FET) and at least one p-channel field effect transistor (p-FET). A continuous dielectric stressor layer, which overlays both the at least one n-FET and the at least one p-FET, contains a first, tensilely stressed region that selectively overlays the at least one n-FET and a second, compressively stressed region that selectively overlays the at least one p-FET. Such a continuous dielectric stressor layer can be readily formed by first depositing a continuous, compressively stressed dielectric layer and then converting a selected region of such a layer from being compressively stressed to being tensilely stressed by ultraviolet (UV) exposure.

### FIELD OF THE INVENTION

This invention relates to high performance complementary metal-oxide-semiconductor (CMOS) devices having a continuous stressor layer containing regions of opposite stresses, as well as to a method for forming such a continuous stressor layer. More specifically, the present invention relates to CMOS devices each comprising at least one high performance n-channel field effect transistor (n-FET) and at least one high performance p-channel field effect transistor (p-FET), while the n-FET is overlaid by a first, tensilely stressed region of the continuous dielectric stressor layer and the p-FET is overlaid by a second, compressively stressed region of the continuous dielectric stressor layer.

### BACKGROUND OF THE INVENTION

Mechanical stresses within a semiconductor device substrate can be used to modulate device performance. For example, in silicon, hole mobility is enhanced when the film is under compressive stress, while the electron mobility is enhanced when the silicon film is under tensile stress. Therefore, compressive and/or tensile stresses can be advantageously created in the channel regions of a p-FET and/or an n-FET in order to enhance the performance of such devices.

However, the same stress component, either compressive or tensile stress, discriminatively affects the performance of a p-FET and an n-FET. In other words, compressive stress enhances the performance of the p-FET, but adversely impacts the performance of the n-FET, while tensile stress enhances the performance of the n-FET, but adversely impacts the performance of the p-FET. Therefore, p-FET and n-FET require different types of stresses for performance enhancement, which imposes a challenge for concurrent fabrication of high performance p-FET and n-FET devices, due to the difficulty in concurrently applying compressive stress to the p-FET and tensile stress to the n-FET.

One conventional approach for creating desired compressive and tensile stresses in the channel regions of p-FET and n-FET devices is to cover the p-FET and the n-FET devices with separate compressively and tensilely stressed dielectric films, respectively, so that tensile and compressive stresses can be respectively applied to the n-FET and p-FET devices.

However, the tensilely and compressively stressed dielectric films in the conventional CMOS devices are typically patterned by lithography and etching, which are prone to misalignments and may result in significant overlay errors (e.g., in the range of about ±20 nm for the 45 nm node devices). Consequently, the tensilely stressed dielectric layer and the compressively stressed dielectric layer cannot be perfectly aligned with each other at their edges, and the boundary region where the tensilely and compressive stressed dielectric layers meet typically contains either an overlap or a gap between these two layers.

FIG. 1A shows a top view of a conventional CMOS device that comprises a p-FET and an n-FET, and FIG. 1B shows a cross-sectional view of the conventional CMOS device through line A-A. Specifically, such a conventional CMOS device comprises a p-FET active region 102 and an n-FET active region 104 that are separated from each other by an isolation region 111. A common gate structure that comprises a patterned gate conductor 106 and a gate metal silicide layer 107 extend over both active regions 102 and 104 and across the isolation region 111. Gate dielectrics 122 and 142, respectively, isolate the p-FET active region 102 and the n-FET active region 104 from the patterned gate conductor 106.

On one hand, a compressively stressed silicon nitride layer 128 selectively overlays the p-FET active region 102, but not the n-FET active region 104. On the other hand, a tensilely stressed silicon nitride layer 148 selectively overlays the n-FET active region 104, but not the p-FET active region 102. An optional etch stop layer 149, which preferably comprises a low temperature oxide (LTO), is provided over the tensilely stressed silicon nitride layer 148. As shown in FIG. 1B, the compressively and tensilely stressed silicon nitride layers 128 and 148 are not perfectly aligned at their edges but overlap significantly at the boundary region 103A. The boundary region 103A therefore has a silicon nitride layer thickness that is twice of the silicon nitride thickness in other regions, which may cause insufficient contact etch. Specifically, if a metal contact (not shown) is formed over the boundary region 103A, such a metal contact (not shown) may not be able to extend through the overlapped silicon nitride at the boundary region 103A, thereby resulting in failure to make contact to the underlying FET components (e.g., the gate conductor 106).

The misalignment between the compressively and tensilely stressed silicon nitride layers and may also form a gap at the boundary region. Specifically, FIG. 2A shows a top view of another conventional CMOS device, which is similar to that shown by FIG. 1A, but comprises separate gate structures for the p-FET 102 and the n-FET 104. FIG. 2B shows a cross-sectional view of this conventional CMOS device through line B-B. A p-FET gate structure that comprises a patterned gate conductor 124 and a gate metal silicide layer 125 extends over the p-FET active region 102, and an n-FET gate structure that comprises a patterned gate conductor 144 and a gate metal silicide layer 145 extends over the n-FET active region 104. Gate dielectrics 122 and 142, respectively, isolate the p-FET active region 102 and the n-FET active region 104 from the patterned gate conductors 124 and 144.

A gap 103B exists between the compressively stressed silicon nitride layer 128 that selectively overlays the p-FET active region 102 and the tensilely stressed silicon nitride layer 148 that selectively overlays the n-FET active region 104. Correspondingly, the etching process typically used for forming metal contact openings through the tensilely or compressively stressed dielectric layers 148 or 128 (and their explicit or implicit optional etch stop layers 149 and 129) may accidentally punch through the underlying FET components at the gap region 103B, causing complete device failure. Further, the gap 103B may allow sodium and other contaminants to diffuse into the underlying substrate region and thereby causes degradation of the device performance.

### SUMMARY OF THE INVENTION

The present invention advantageously overcomes the above-mentioned drawbacks of the conventional CMOS devices by providing a continuous dielectric stressor layer that comprises a first, tensilely stressed region and a second, compressively stressed region. There is no gap or overlap between the first, tensilely stressed region and the second, compressively stressed region, thereby completely eliminating the above-mentioned problems associated with overlap or gap in the stressor layers of the conventional CMOS devices. The first, tensilely stressed region selectively overlays an n-FET to apply the desired tensile stress to the n-FET, and the second, compressively stressed region selectively overlays a p-FET to apply the desired compressive stress to the p-FET. In this manner, the device performance of both the n-FET and the p-FET is optimized.

In one aspect, the present invention relates to a semiconductor device comprising:
at least one n-channel field effect transistor (n-FET) and at least one p-channel field effect transistor (p-FET) that are spaced apart from each other; and
a continuous dielectric stressor layer overlaying both the at least one n-FET and the at least one p-FET, wherein the continuous dielectric stressor layer comprises a first region that is tensilely stressed and a second region that is compressively stressed, wherein the first, tensilely stressed region selectively overlays the at least one n-FET, and wherein the second, compressively stressed region selectively overlays the at least one p-FET.

The continuous dielectric stressor layer may comprise any suitable dielectric materials with the corresponding stress profiles. Preferably, the continuous dielectric stressor layer comprises SiCN.

The n-FET and the p-FET as described hereinabove may comprise a common gate structure that is located under the continuous dielectric stressor layer. Alternatively, the n-FET and the p-FET may comprise separate gate structures that are isolated from each other and are respectively located under the first, tensilely stressed region and the second, compressively stressed region of the continuous dielectric stressor layer.

In another aspect, the present invention relates to a method for forming a semiconductor device comprising:
forming at least one n-channel field effect transistor (n-FET) and at least one p-channel field effect transistor (p-FET) that are spaced apart from each other;
forming a continuous dielectric stressor layer over both the at least one n-FET and the at least one p-FET, wherein the continuous dielectric stressor layer is compressively stressed;
forming a patterned ultraviolet (UV)-blocking layer over the continuous dielectric stressor layer, wherein a first region of the continuous dielectric stressor layer overlaying the n-FET is not covered by the patterned UV-blocking layer, and wherein a second region of the continuous dielectric stressor layer overlaying the p-FET is covered by the patterned UV-blocking layer;
treating the continuous dielectric stressor layer with UV light for a sufficient period of time so that the first region that is not covered by the patterned UV-blocking layer becomes tensilely stressed, and wherein the second region of the continuous dielectric stressor layer remains compressively stressed; and
removing the patterned UV-blocking layer.

The compressively stressed, continuous dielectric stressor layer as mentioned hereinabove preferably comprises SiCN that can be readily formed by a plasma-enhanced chemical vapor deposition (PECVD) process or a high-density plasma (HDP) process that is carried out at a temperature ranging from about 300° C. to about 450° C., a pressure ranging from about 0.5 torr to about 6 torr, and a plasma power level ranging from about 100 W to about 1500 W using processing gases comprising trimethylsilane, NH₃, and N₂.

The patterned UV-blocking layer may comprise any suitable UV-blocking material, such as metal nitrides, metal oxides, silicon nitrides, silicon oxides, silicon carbides, polymers, etc. In a particularly preferred embodiment of the present invention, the patterned UV-blocking layer comprises TiN.

The compressively stressed, continuous dielectric stressor layer is preferably treated by UV light for a duration from about 2.5 minutes to about 15 minutes to achieve the desired stress conversion in the first region. More preferably, the UV light treatment is carried out using UV light having a wavelength ranging from about 180 nm to about 600 nm and an energy level ranging from about 10 mW/cm² to about 1000 mW/cm².

A further aspect of the present invention relates to a continuous dielectric stressor layer comprising a first region that is tensilely stressed and a second region that is compressively stressed, wherein no gap or overlap is present between said first and second regions.

Yet another aspect of the present invention relates to a method for forming such a continuous dielectric stress layer, comprising:
forming a continuous, compressively stressed dielectric layer;
forming a patterned ultraviolet (UV)-blocking layer over the continuous, compressively stressed dielectric layer, thereby defining a first region in the continuous, compressively stressed dielectric layer that is not covered by said patterned UV-blocking layer and a second region that is covered by said patterned UV-blocking layer;
treating the continuous, compressively stressed dielectric layer with UV light for a sufficient period of time, so that the first region not covered by the patterned UV-blocking layer becomes tensilely stressed, and wherein the second region covered by the patterned UV-blocking layer remains compressively stressed; and
removing the patterned UV-blocking layer.

Other aspects, features and advantages of the invention will be more fully apparent from the ensuing disclosure and appended claims.

### BRIEF DESCRIPTION OF THE DRAWINGS

FIG. 1A is a top view of a conventional CMOS device comprising an n-FET and a p-FET with separate tensile and compressive stressor layers that are overlapped with each other at the boundary region.

FIG. 1B is a cross-sectional view of the conventional CMOS device of FIG. 1A along line A-A.

FIG. 2A is a top view of a conventional CMOS device comprising an n-FET and a p-FET with separate tensile and compressive stressor layers, while a gap exists between such stressor layers at the boundary region.

FIG. 2B is a cross-sectional view of the conventional CMOS device of FIG. 2A along line B-B.

FIG. 3 is a cross-sectional view of an improved CMOS device comprising an n-FET and a p-FET with a continuous dielectric stressor layer located thereover, while a first region of the continuous dielectric stressor layer that selectively overlays the n-FET is tensilely stressed, and a second region of the continuous dielectric stressor layer that selectively overlays the p-FET is compressively stressed, according to one embodiment of the present invention.

FIGS. 4-10 illustrate exemplary processing steps for forming a CMOS device having separate n-FET and p-FET gate structures, while a continuous dielectric stressor layer with regions of opposite stress types overlays both the n-FET and p-FET gate structures, according to one embodiment of the present invention.

FIG. 11 shows a cross-section view of a CMOS device having a common gate structure for both the n-FET and the p-FET, while a continuous dielectric stressor layer with regions of opposite stress types overlays the common gate structure, according to one embodiment of the present invention.

FIG. 12 is a graph that plots the stress values of a continuous SiCN layer with initial compressive stress as a function of time over which the continuous SiCN layer is exposed to UV light.

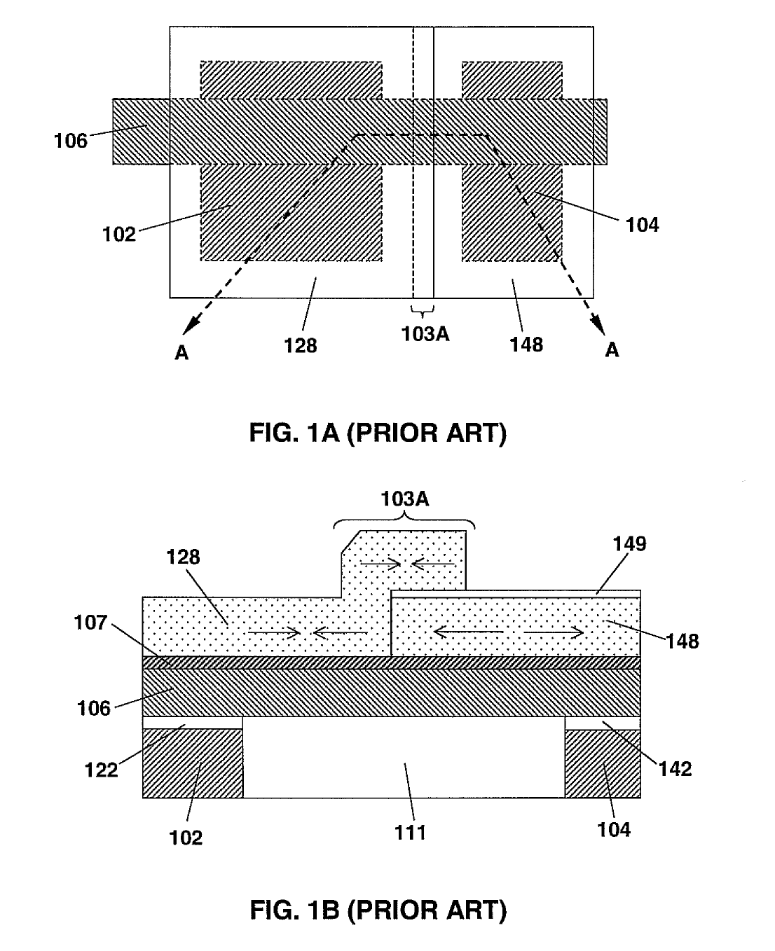

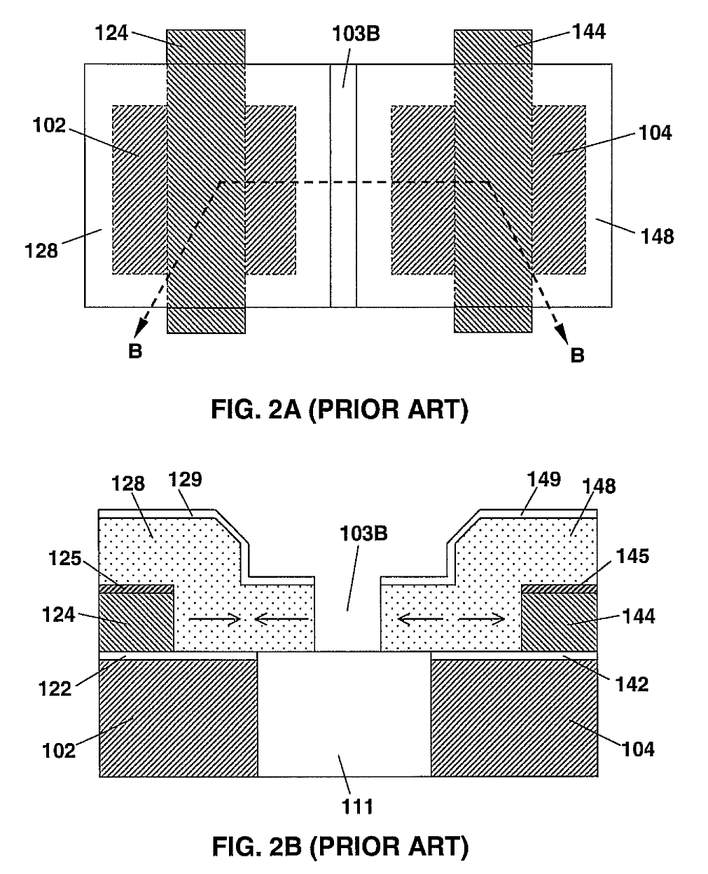

### DETAILED DESCRIPTION OF THE INVENTION, AND PREFERRED EMBODIMENTS THEREOF

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The term “continuous” as used herein refers to a layer or a film that is formed by a single deposition step and contains no gap or overlap.

The term “SiCN” as used herein refers to dielectric materials having the formula SiₓC_{y}N_{z}, wherein x+y+z=1. Preferably, x ranges from about 0.2 to about 0.7, y ranges from about 0.1 to about 0.5, and z ranges from about 0.01 to about 0.6.

The present invention provides an improved CMOS device that comprises at least one n-FET and at least one p-FET with a continuous dielectric stressor layer located thereon. Such a continuous dielectric stressor layer comprises regions of opposite stress types for respectively applying desired stresses to the n-FET and the p-FET, while no gap or overlap exists between such regions of opposite stress types. Therefore, various problems commonly associated with overlap or gap in the stressor layers of conventional CMOS devices can be completely eliminated by the present invention.

Moreover, the present invention provides a simple and cost-effective method for forming the above-described continuous dielectric stressor layer. Specifically, UV treatment is conducted on a selected portion of a compressively stressed dielectric layer to convert compressive stress contained by this portion into tensile stress. The remaining untreated portion of the compressively stressed dielectric layer remains compressively stressed. The resulting dielectric layer therefore comprises a UV-treated portion that is tensilely stressed and an un-treated portion that is compressively stressed. Such a dielectric layer can be used in CMOS devices for applying differential stresses to n-FETs and p-FETs, as described hereinabove, but it can also be used, without limitation, in other semiconductor devices such as resistors, diodes, and electrically programmable fuses.

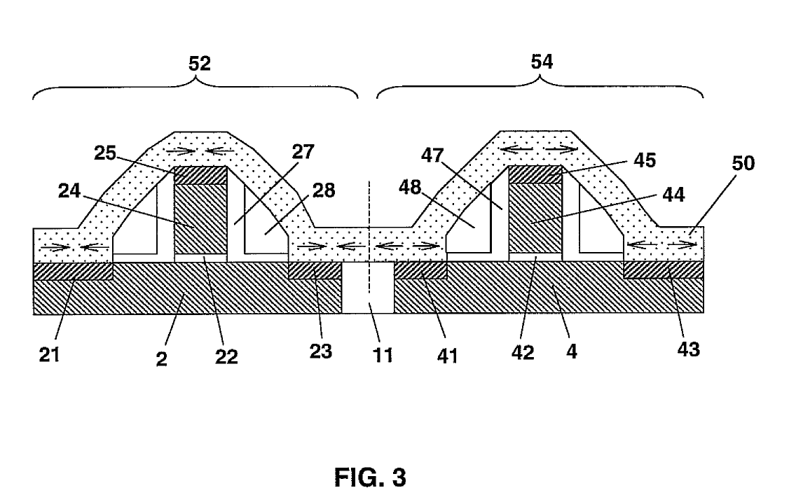

FIG. 3 shows a cross-sectional view of a CMOS device with such a dielectric layer as described hereinabove, according to one embodiment of the present invention.

Specifically, the CMOS device comprises a p-FET that is located over a p-FET active region 2 and an n-FET that is located over an n-FET active region 4. The p-FET active region 2 and the n-FET active region 4 are located in the same semiconductor substrate (not shown) and are separated from each other by an isolation region 11. The p-FET active region 2 contains p-type source and drain doping regions (not shown) with source and drain silicide contacts 21 and 23. Similarly, the n-FET active region 4 contains n-type source and drain doping regions (not shown) with source and drain silicide contacts 41 and 43.

Separate gate structures, one of which comprises: (1) a first gate conductor 24, (2) a first gate metal silicide 25, and (3) optional spacers 27 and 28 and the other of which comprises: (1) a second gate conductor 44, (2) a second gate metal silicide 45, and (3) optional spacers 47 and 48, are provided over the p-FET active region 2 and the n-FET active region 4, respectively. Gate dielectrics 22 and 42 respectively isolate the p-FET active region 2 and the n-FET active region 4 from the first and second gate conductors 24 and 44.

A continuous dielectric stressor layer 50 overlays both the p-FET active region 2 and the n-FET active region 4. The continuous dielectric stressor layer 50 contains a first region 52 that is compressively stressed and a second region 54 that is tensilely stressed (as indicated by the arrowheads in FIG. 3), while the first, compressively stressed region 52 selectively overlays the p-FET active region 2 and the second, tensilely stressed region 54 selectively overlays the n-FET active region 4. As shown in FIG. 3, no gap or overlap exists between the first, compressively stressed region 52 and the second, tensilely stressed region 54.

The continuous dielectric stressor layer 50 may comprise any suitable dielectric material whose stress profiles can be modulated or adjusted. Preferably, but not necessarily, the continuous dielectric stressor layer 50 comprises SiCN.

The above-described continuous dielectric stressor layer 50 can be formed by a selective UV-treatment process, which is found by the inventors of the present invention to be particularly effective in converting compressive stress of a dielectric film into tensile stress.

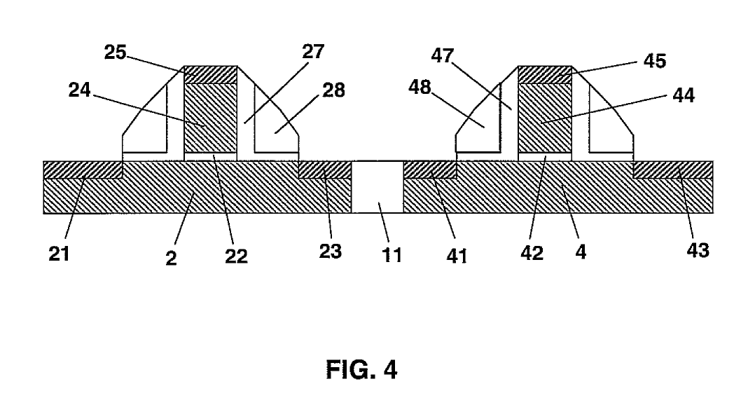

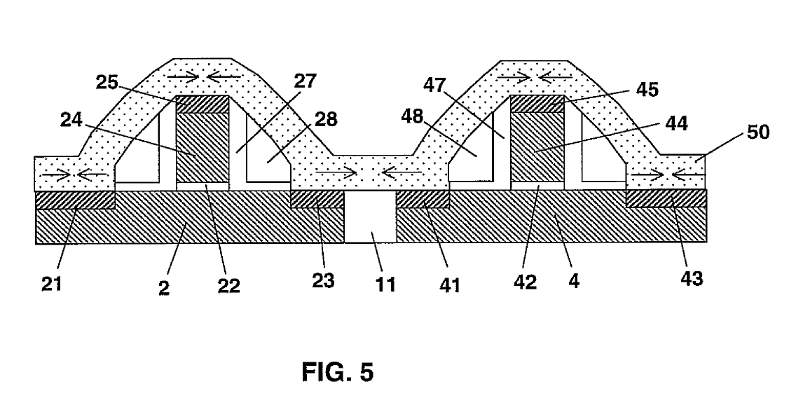

Exemplary processing steps that can be used for forming the continuous dielectric stressor layer 50 in the CMOS device structure illustrated by FIG. 3 will now be described in greater detail by referring to the accompanying drawings in FIGS. 4-10. Note that in these drawings, which are not drawn to scale, like and/or corresponding elements are referred to by like reference numerals. It is further noted that in the drawings only one n-FET and one p-FET are shown. Although illustration is made to such an embodiment, the present invention is not limited to the formation of any specific number of n- and/or p-FET devices.

Reference is first made to FIG. 4, which shows formation of a p-FET over a p-FET active region 2 and an n-FET over an n-FET active region 4. The n-FET and p-FET active regions 2 and 4 are located in the same semiconductor substrate (not shown) and are isolated from each other by the isolation region 11.

The semiconductor substrate (not shown), in which the p-FET active region 2 and the n-FET active region 4 are located, may comprise any semiconductor material including, but not limited to: Si, SiC, SiGe, SiGeC, Ge alloys, GaAs, InAs, InP, as well as other III-V or II-VI compound semiconductors. The semiconductor substrate (not shown) may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate (not shown) be composed of a Si-containing semiconductor material, i.e., a semiconductor material that includes silicon. The semiconductor substrate (not shown) may be doped, undoped or contain doped and undoped regions therein. The p-FET active region 2 may be formed of a first doped (n- or p-) region in the semiconductor substrate (not shown), while the n-FET active region 4 may be formed of a second doped (n- or p-) region. Further, the p-FET and n-FET active regions 2 and 4 may have the same or different conductivities and/or doping concentrations.

The isolation region 11 is typically formed into the semiconductor substrate (not shown) to provide isolation between the p-FET and n-FET active regions 2 and 4. The isolation region 11 may be a trench isolation region or a field oxide isolation region. The trench isolation region is formed utilizing a conventional trench isolation process well known to those skilled in the art. For example, lithography, etching and filling of the trench with a trench dielectric may be used in forming the trench isolation region. Optionally, a liner may be formed in the trench prior to trench fill, a densification step may be performed after the trench fill and a planarization process may follow the trench fill as well. The field oxide may be formed utilizing a so-called local oxidation of silicon process.

After forming the at least one isolation region 11 within the semiconductor substrate (not shown), patterned gate dielectric layers 22 and 42 are formed respectively over the p-FET active region 2 and the n-FET active region 4. The gate dielectric layers 22 and 42 can be formed by a thermal growing process such as, for example, oxidation, nitridation or oxynitridation. Alternatively, the gate dielectric layers 22 and 42 can be formed by a deposition process such as, for example, chemical vapor deposition (CVD), plasma-assisted CVD, atomic layer deposition (ALD), evaporation, reactive sputtering, chemical solution deposition and other like deposition processes. The gate dielectric layers 22 and 42 may also be formed utilizing any combination of the above processes.

The gate dielectric layers 22 and 42 may be comprised of any suitable insulating material, which includes, but is not limited to: an oxide, nitride, oxynitride and/or silicate including metal silicates and nitrided metal silicates. In one embodiment, it is preferred that the gate dielectric layers 22 and 42 are comprised of an oxide such as, for example, SiO₂, HfO₂, ZrO₂, Al₂O₃, TiO₂, La₂O₃, SrTiO₃, LaAlO₃, and mixtures thereof. The physical thickness of the gate dielectric layers 22 and 42 may vary, but typically, the gate dielectric layers 22 and 42 each has a thickness from about 0.5 to about 10 nm, with a thickness from about 0.5 to about 3 nm being more typical.

After forming the patterned gate dielectric layers 22 and 42, patterned gate conductors 24 and 44, which preferably comprises polysilicon, are respectively formed over the n-FET and p-FET active regions 2 and 4, utilizing a known deposition process such as, for example, physical vapor deposition, CVD or evaporation, followed by a known gate patterning process, such as lithography and etching. The gate conductors 24 and 44 may be doped or undoped. If doped, an in-situ doping deposition process may be employed in forming the same. Alternatively, doped gate conductors 24 and 44 can be formed by deposition, ion implantation and annealing. The thickness, i.e., height, of the gate conductors 24 and 44 may vary depending on the deposition process employed. Typically, the gate conductors 24 and 44 each have a vertical thickness from about 20 to about 180 nm, with a thickness from about 40 to about 150 nm being more typical.

Optionally, but not necessarily, gate silicide contacts 25 and 45 are formed over the gate conductors 24 and 44 by a known salicidation process, which is not described in detail here in order to avoid obscuring the present invention. Further, optional spacers 27, 28, 47 and 48, as well as other additional structures (e.g., cap layers and/or diffusion barrier layers) that are commonly included in MOS gate structures, can be formed around the gate conductors 24 and 44, as shown in FIG. 3.

A blanket compressively stressed dielectric layer 50 is then deposited over both the p-FET and n-FET active regions 2 and 4. The compressively stressed dielectric layer 50 preferably comprises SiCN, and it can be formed by, for example, a plasma-enhanced chemical vapor deposition (PECVD) process or a high-density plasma (HDP) process that is carried out at a temperature ranging from about 300° C. to about 450° C., a pressure ranging from about 0.5 torr to about 6 torr, and a plasma power level ranging from about 100 to about 1500 W using processing gases comprising trimethylsilane, NH₃, and N₂. Preferably, the compressively stressed dielectric layer 50 has a thickness ranging from about 10 nm to about 1000 nm, more preferably from about 20 nm to about 500 nm, and most preferably from about 30 nm to about 150 nm.

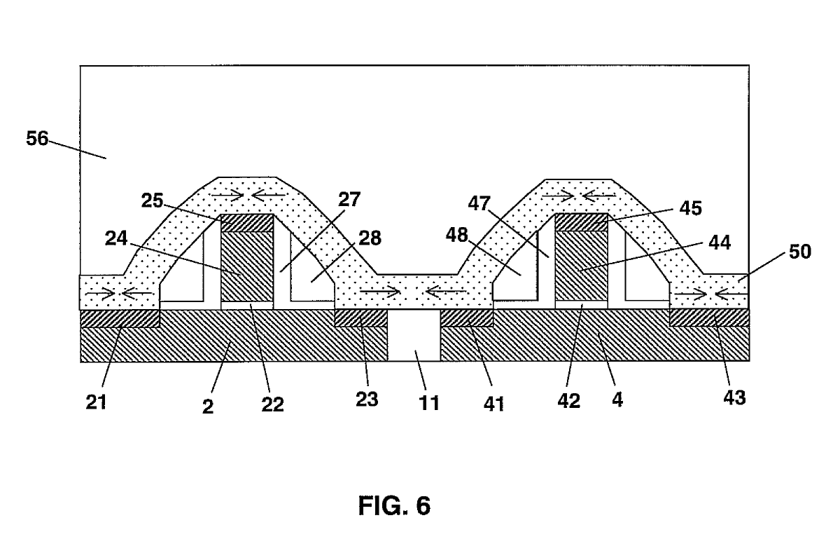

Subsequently, an interlevel dielectric (ILD) layer 56 is deposited over the entire structure, as shown in FIG. 6. The ILD layer 56 preferably comprises an oxide that is formed by either a high-density plasma (HDP) deposition process or by a tetraethylorthosilicate (TEOS)-based deposition process.

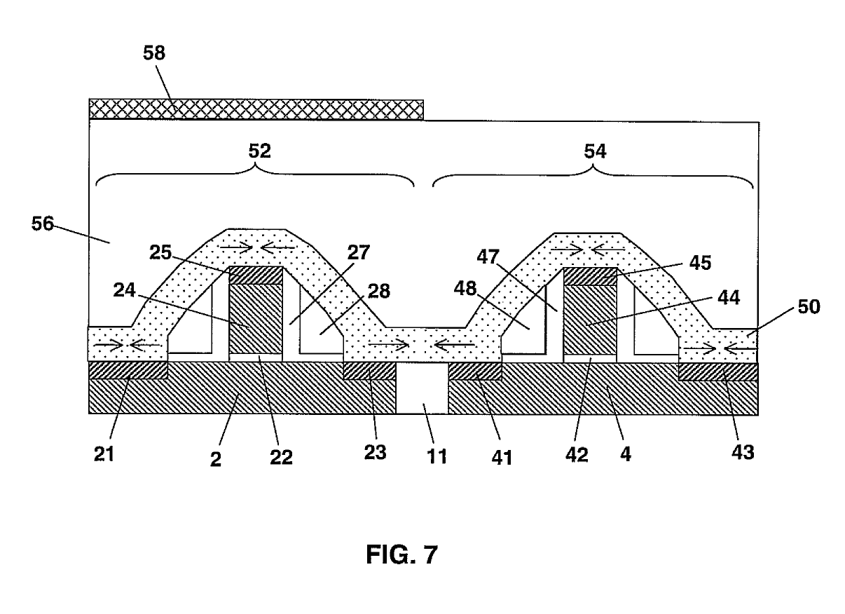

Subsequently, a patterned ultraviolet (UV)-blocking layer 58 is deposited over the ILD layer 56 to selectively cover the p-FET active region 2, but not the n-FET active region 4, as shown in FIG. 7. The blanket compressively stressed dielectric layer 50 is therefore defined by the patterned UV-blocking layer 58 into a first region 52 that is covered by the patterned UV-blocking layer 58 and a second region 54 that is not covered by the patterned UV-blocking layer 58.

Any suitable UV-blocking material, such as metals, metal nitrides, metal oxides, silicon nitrides, silicon oxides, silicon carbides, polymers, etc., can be used to form the patterned UV-blocking layer 58. Preferably, the patterned UV-blocking layer 58 comprises at least one of TiN, Al, and TaN. More preferably, the patterned UV-blocking layer 58 comprises TiN.

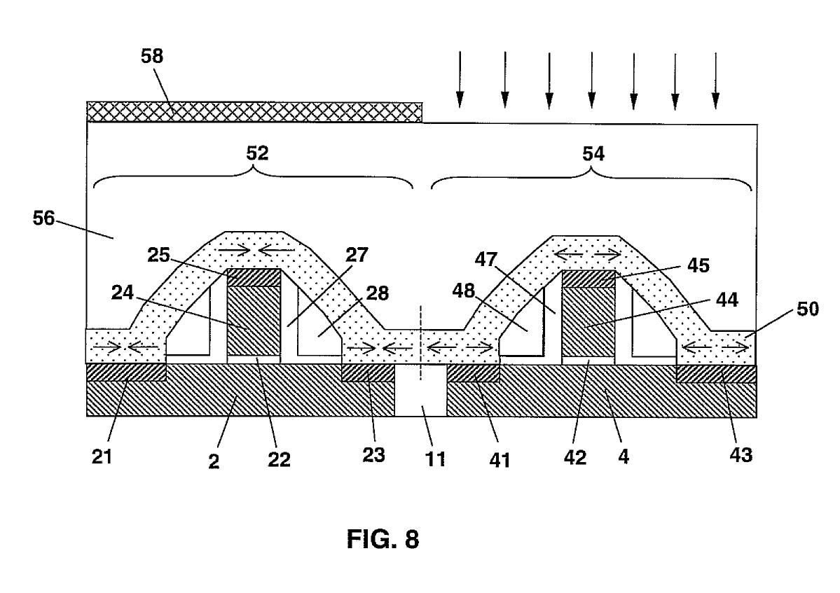

The entire structure as shown in FIG. 7 is then exposed to ultraviolet (UV) light of a wavelength ranging from about 180 nm to about 600 nm and an energy level ranging from about 10 mW/cm² to about 1000 mW/cm². When the UV-treatment is carried out for a sufficient period of time, the second, uncovered region 54 of the continuous dielectric stressor layer 50 is converted from being compressively stressed to being tensilely stressed, as shown in FIG. 8. However, the first, covered region 52 of the continuous dielectric stressor layer 50 remains compressively stressed.

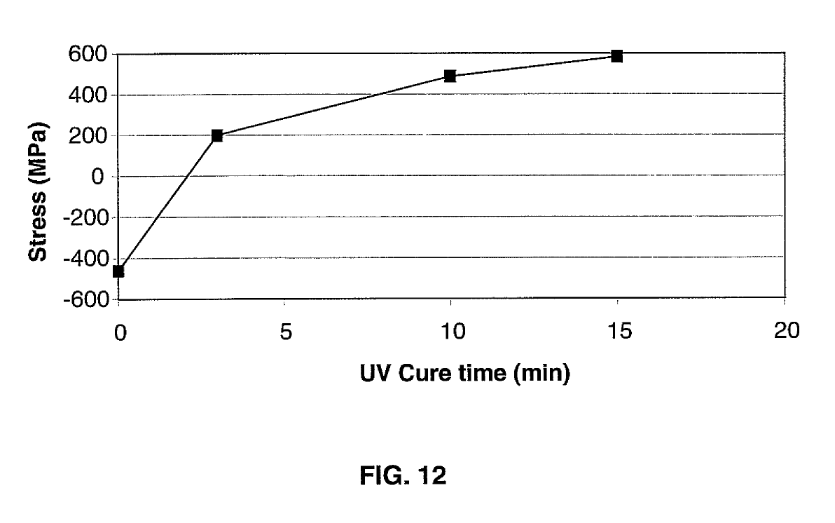

The inventors of the present invention have discovered that the stress profiles of certain dielectric layers, such as SiCN layers, can be modulated by UV-treatment. Specifically, a SiCN layer, which initially contains compressive stress, can be completely released of such compressive stress after being exposed to UV light for about 2 minutes. Further exposure of such a SiCN layer to UV light will generate tensile stress therein, and the amount of tensile stress is directly correlated with the UV exposure time, as indicated by the graph shown in FIG. 12.

Therefore, UV treatment can be advantageously used for selectively converting compressive stress in certain regions of a continuous dielectric layer into tensile stress, thereby forming a continuous dielectric stressor layer with regions of opposite stress types. When the UV treatment is carried out for a duration ranging from about 2.5 minutes to about 15 minutes, a tensile stress ranging from about 100 MPa to about 600 MPa is created. Higher stress (i.e., >600 MPa) can be achieved with optimized UV exposure time and/or SiCN film composition.

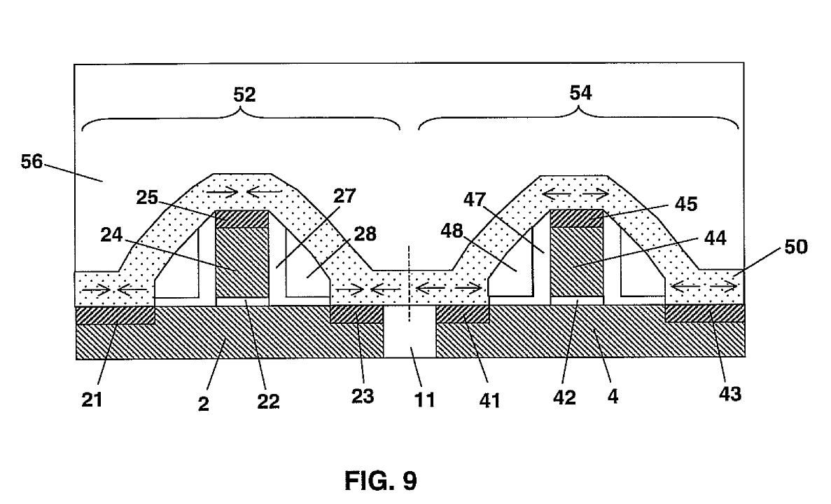

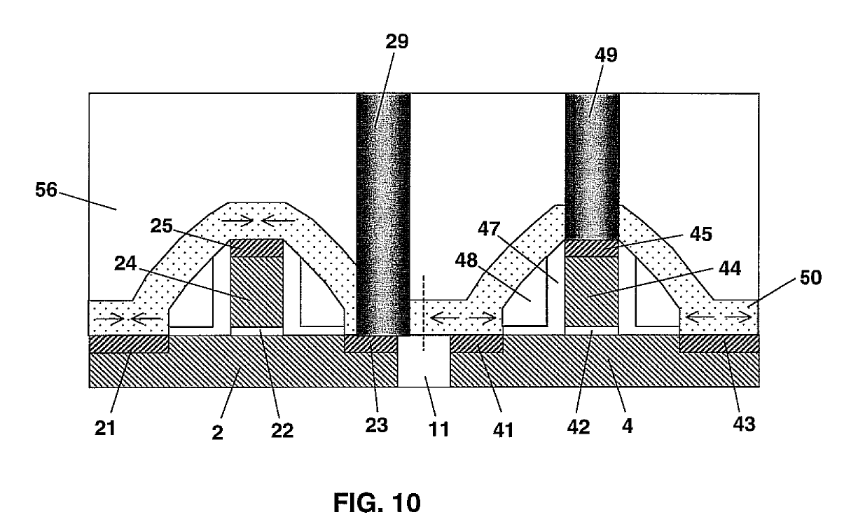

The patterned UV-blocking layer 58 is removed after the UV-treatment step, and metal contacts 29 and 49 are subsequently formed through the ILD layer 56 and the continuous dielectric stressor layer 50 into contact with the p-FET and the n-FET, respectively, as shown in FIGS. 9 and 10.

Subsequently, conventional back-end-of-line processing steps, which are not described herein in detail, can be carried out to form a complete CMOS device containing both a p-FET and an n-FET.

The n-FET and p-FET of the present invention may have separate gate structures, as shown hereinabove by FIGS. 3-10, but they may also comprise a common gate structure (not shown) that extends over both active regions 2 and 4 and across the isolation region 11.

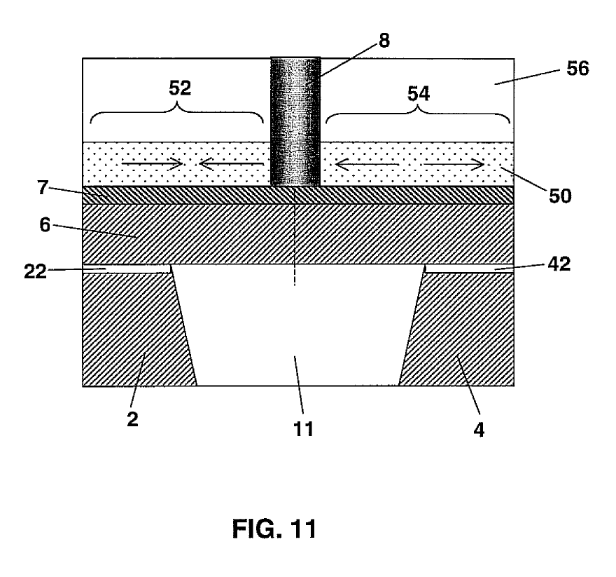

FIG. 11 shows a cross-sectional view of an improved CMOS device that is similar to that shown in FIGS. 3-10, except that a common gate structure, which comprises a patterned gate conductor 6 and a gate metal silicide 7, extends over both the p-FET active region 2 and the n-FET active region 4. A gate metal contact 8 is formed through the ILD layer 56 and the continuous dielectric stressor layer 50 to provide access to the common gate structure.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A semiconductor device comprising:
at least one n-channel field effect transistor (n-FET) and at least one p-channel field effect transistor (p-FET) that are spaced apart from each other; and
a continuous dielectric stressor layer overlaying both the at least one n-FET and the at least one p-FET, wherein said continuous dielectric stressor layer comprises a first region that is tensilely stressed and a second region that is compressively stressed, wherein the first, tensilely stressed region selectively overlays the at least one n-FET, and wherein the second, compressively stressed region selectively overlays the at least one p-FET.

2. The semiconductor device of claim 1, wherein the continuous dielectric stressor layer comprises SiₓC_{y}N_{z}, and wherein x+y+z=1.

3. The semiconductor device of claim 2, wherein x ranges from about 0.2 to about 0.7, y ranges from about 0.1 to about 0.5, and z ranges from about 0.01 to about 0.6.

4. The semiconductor device of claim 1, wherein the n-FET and the p-FET comprise a common gate structure that is located under the continuous dielectric stressor layer.

5. The semiconductor device of claim 1, wherein the n-FET and the p-FET comprise separate gate structures that are isolated from each other and are respectively located under the first and second regions of the continuous dielectric stressor layer.

6. A method for forming a semiconductor device comprising:
forming at least one n-channel field effect transistor (n-FET) and at least one p-channel field effect transistor (p-FET) that are spaced apart from each other;
forming a continuous dielectric stressor layer over both the at least one n-FET and the at least one p-FET, wherein said continuous dielectric stressor layer is compressively stressed;
forming an interlevel dielectric layerr upon the continuous dielectric stressor layer;
forming a patterned ultraviolet (UV)-blocking layer upon the interlevel dielectric layer and over the continuous dielectric stressor layer, wherein a first region of the continuous dielectric stressor layer overlaying the n-FET is not covered by said patterned UV-blocking layer, and wherein a second region of the continuous dielectric stressor layer overlaying the p-FET is covered by said patterned UV-blocking layer;
treating the continuous dielectric stressor layer with UV light for a sufficient period of time so that the first region that is not covered by the patterned UV-blocking layer becomes tensilely stressed, and wherein the second region of the continuous dielectric stressor layer remains compressively stressed; and
removing the patterned UV-blocking layer.

7. The method of claim 6, wherein the continuous dielectric stressor layer comprises SiₓC_{y}N_{z}, and wherein x+y+z=1.

8. The method of claim 7, wherein x ranges from about 0.2 to about 0.7, y ranges from about 0.1 to about 0.5, and z ranges from about 0.01 to about 0.6.

9. The method of claim 7, wherein the continuous dielectric stressor layer is formed by a plasma-enhanced chemical vapor deposition (PECVD) process or a high-density plasma deposition (HDP) process that is carried out at a temperature ranging from about 300° C. to about 450° C., a pressure ranging from about 0.5 torr to about 6 torr, and a plasma power level ranging from about 100 W to about 1500 W using processing gases comprising trimethylsilane, NH₃, and N₂.

10. The method of claim 6, wherein the patterned UV-blocking layer comprises a UV-blocking material selected from the group consisting of metals, metal nitrides, metal oxides, silicon nitrides, silicon oxides, silicon carbides, polymers, and combinations thereof.

11. The method of claim 6, wherein the continuous dielectric stressor layer is treated with UV light for a duration ranging from about 2.5 minutes to about 15 minutes.

12. The method of claim 6, wherein the continuous dielectric stressor layer is treated with UV light having a wavelength ranging from about 180 nm to about 600 nm and an energy level ranging from about 10 mW/cm² to about 1000 mW/cm².

13. The method of claim 6, wherein the n-FET and the p-FET comprise a common gate structure that is located under the continuous dielectric stressor layer.

14. The method of claim 6, wherein the n-FET and the p-FET comprise separate gate structures that are isolated from each other and are respectively located under the first and second regions of the continuous dielectric stressor layer.

15. A continuous dielectric stressor layer comprising a first region that is tensilely stressed and a second region that is compressively stressed.

16. The continuous dielectric stressor layer of claim 15, comprising SiₓC_{y}N_{z}, wherein x+y+z=1.

17. A method for forming the continuous dielectric stressor layer, comprising:
forming a continuous, compressively stressed dielectric layer over a substrate;
forming an interlevel dielectric layer over the continuous compressively stressed dielectric layer;
forming a patterned ultraviolet (UV)-blocking layer upon the interlevel dielectric layer and over the continuous, compressively stressed dielectric layer, thereby defining a first region in the continuous, compressively stressed dielectric layer that is not covered by said patterned UV-blocking layer and a second region that is covered by said patterned UV-blocking layer;
treating the continuous, compressively stressed dielectric layer with UV light for a sufficient period of time, so that the first region not covered by the patterned UV-blocking layer becomes tensilely stressed, and wherein the second region covered by the patterned UV-blocking layer remains compressively stressed; and
removing the patterned UV-blocking layer.

18. The method of claim 17, wherein the continuous, compressively stressed dielectric layer is formed by a plasma-enhanced chemical vapor deposition (PECVD) process or a high-density plasma (HDP) process that is carried out at a temperature ranging from about 300° C. to about 450° C., a pressure ranging from about 0.5 torr to about 6 torr, and a plasma power level ranging from about 100 W to about 1500 W using processing gases comprising trimethylsilane, NH₃, and N₂.

19. The method of claim 17, wherein the patterned UV-blocking layer comprises a UV-blocking material selected from the group consisting of metal nitrides, metal oxides, silicon nitrides, silicon oxides, silicon carbides, polymers, and combinations thereof.

20. The method of claim 17, wherein the continuous compressively stressed dielectric layer is treated with UV light for a duration ranging from about 2.5 minutes to about 15 minutes.
